(19) United States
(12) Patent Application Publication
(10) Pub. No.: US 2021/0408317 A1
(43) Pub. Date: Dec. 30, 2021

(54) HARVESTABLE INDOOR ENERGY METER

(71) Applicants: Utica Leaseco, LLC, Rochester Hills, MI (US); ALTA DEVICES, INC., Sunnyvale, CA (US)

(72) Inventor: James G. NEFF, Sunnyvale, CA (US)

(21) Appl. No.: 17/285,030

(22) PCT Filed: Jul. 30, 2019
(86) PCT No.: PCT/US2019/044122

§ 371 Date: Sep. 1, 2021

Related U.S. Application Data
(60) Provisional application No. 62/746,971, filed on Oct. 17, 2018.

(51) Int. Cl. H01L 31/0735; H01L 31/02; H01L 31/0392

(52) U.S. Cl. CPC H01L 31/0735; H04W 4/80; H01L 31/03926; H01L 31/02016

(57) ABSTRACT

An indoor light energy harvesting meter is described that includes a solar module including at least one photovoltaic cell to capture ambient light energy; and a circuit module coupled to the solar module. The circuit module may include a power management circuit configured to convert the ambient light energy captured by the solar module into electric energy; and a micro-controller configured to control the power management circuit and to receive the electric energy from the power management circuit to monitor an amount of indoor harvestable power. The micro-controller may monitor the amount of indoor harvestable power and generate parameters including one or more of an accumulated harvestable power, an instantaneous harvestable power, or a peak instantaneous harvestable power. The indoor light energy harvesting meter may include a display coupled to the micro-controller and configured to display one or more parameters associated with the amount of indoor harvestable power.

### CROSS REFERENCE TO RELATED APPLICATION

The present application claims priority to and the benefit from U.S. Provisional Patent Application No. 62/746,971, entitled “HARVESTABLE INDOOR ENERGY METER,” and filed on Oct. 17, 2018, the contents of which are incorporated herein by reference in their entirety.

### BACKGROUND

This disclosure relates to an energy meter that determines harvestable or collectable amounts of light energy in given indoor locations.

With the growing proliferation of Internet of Things (IoT) devices and other similar devices capable of connecting, collecting, and/or exchanging data, or activating certain functions (e.g., sensors, actuators), the need for autonomous or self-sufficient power solutions to provide power for such devices is expanding. Harvesting or collecting energy from indoor lighting is one way to provide such power.

However, every indoor lighting environment is unique, with an infinite variety of bulb types/spectra (e.g., halogen, LED, fluorescent, incandescent, etc.), variable lux levels, and different duty cycles (e.g., dark/light cycles), as well as possible outside lighting through windows or glass walls. Determining how much power may be generated in a given indoor location is difficult to calculate and involves measurement of lux level, availability of lighting spectra, and assumption of duty cycle. Moreover, because IoT devices and/or other data gathering or activation devices may be positioned or placed in very different places in an indoor environment to optimize their operation, it becomes challenging to determine the exact lighting conditions to be experienced by the indoor energy harvesting solution in different possible operating locations within a room or other indoor space.

The availability of an instrument that could reliably measure and report any location's harvestable illumination energy could be quite valuable to a systems installer to identify the best location for a device and/or the best device for a particular location based on the amount of harvestable energy.

### BRIEF DESCRIPTION OF THE DRAWINGS

FIG. 1 is a diagram that illustrates an example of an indoor environment, in accordance with aspects of this disclosure.

FIGS. 2A and 2B are diagrams that illustrate examples of an indoor light energy harvesting meter placed on different types of surfaces, in accordance with aspects of this disclosure.

FIG. 3 is a block diagram that illustrates an example architecture of an indoor light energy harvesting meter, in accordance with aspects of this disclosure.

FIG. 4 is a diagram that illustrates an example of a flexible packaging of an indoor light energy harvesting meter, in accordance with aspects of this disclosure.

FIG. 5 illustrates an example of a flow diagram of a process for operating an indoor light energy harvesting meter, in accordance with aspects of this disclosure.

### SUMMARY OF THE DISCLOSURE

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its purpose is to present some concepts of one or more aspects in a simplified form as a prelude to the more detailed description that is presented later.

In an aspect, an indoor light energy harvesting meter is described that includes a solar module including at least one photovoltaic cell to capture ambient light energy; and a circuit module coupled to the solar module. The circuit module may include a power management circuit configured to convert the ambient light energy captured by the solar module into electric energy; and a micro-controller configured to control the power management circuit and to receive the electric energy from the power management circuit to monitor an amount of indoor harvestable power.

In another aspect, a method for determining indoor light energy harvesting conditions is described that includes enabling an indoor light energy harvesting meter having a solar module and a circuit module with a power management circuit and a micro-controller; capturing, by at least one photovoltaic cell in the solar module, ambient light energy; converting, by the power management circuit, the light energy into electrical energy; monitoring, by the micro-controller, an amount of indoor harvestable power based on the electrical energy; generating, by the micro-controller, one or more parameters associated with the amount of indoor harvestable power; and providing the one or more parameters to a user.

### DETAILED DESCRIPTION

This disclosure describes an energy meter or energy measuring instrument that determines harvestable light energy in different types of indoor locations. As used herein the terms “photovoltaics” and “solar cells” may be used interchangeably to refer to one or more portions of an optoelectronic system or component that produce voltage and/or electric current when exposed to light. It is also to be understood that a reference to a single “photovoltaic” and “solar cell” may also refer to instances of multiples of such devices or structures. Also, as used herein the terms “indoor light,” “indoor lighting,” “ambient light,” “indoor light energy,” “indoor lighting energy,” “ambient light energy,” and similar terms may refer to light available for harvesting, collecting, or capturing within an indoor environment, whether the light that is available is entirely artificially generated, external light (e.g., solar) that is available within the indoor environment, or a combination of both.

As mentioned above, IoT devices and/or other data gathering or activation devices (e.g., sensors, actuators) proliferate, the need for autonomous power solutions to provide power for such devices (e.g., self-powered devices) is expanding. Harvesting energy from indoor lighting is one way to provide such power. Such an approach avoids the need for power to be provided by batteries or cumbersome cables, making installation, operation, and/or maintenance of the devices much simpler.

However, every indoor lighting environment has a unique set of lighting conditions (e.g., spatial and/or temporal lighting conditions), as there is a wide range of bulb types/spectra (e.g., halogen, LED, fluorescent, incandescent, etc.), variable lux levels, and different duty cycles (e.g., dark/light cycles), as well as possible outside lighting that reaches the indoor environment through windows or glass walls. Determining how much power may be generated in a given indoor location is difficult to calculate and involves measurement of lux level, availability of lighting spectra, and assumption of duty cycle. Moreover, because IoT devices, data gathering devices, and/or activation devices may be positioned or placed in very different places in an indoor environment to optimize their operation, it becomes challenging to determine the exact lighting conditions to be experienced by the indoor energy harvesting solution in different possible operating locations within a room or other indoor space.

The availability of an instrument (e.g., an instrument that is small, portable, flexible or non-flexible, and/or autonomous or self-powered) that could reliably measure and report any location's harvestable illumination energy could be quite valuable to a systems installer.

This disclosure describes an indoor light energy harvesting meter that is a compact, flexible or non-flexible, and/or lightweight sensor instrument comprised of solar module (e.g., with one or more solar or photovoltaic cells), a power controller/Maximum Power Point Tracking (MPPT), an electrical load (e.g., such as a resistive load, a light emitting diode (LED) or other visual indicator), a microcontroller and/or other measurement electronics with a clock or timing function, and a display for data reporting. These components may be integrated into a flexible circuit and encapsulated with flexible packaging such that the instrument could be placed almost anywhere with minimal requirements.

An energy storage component, such as a battery, for example, could also be incorporated into the indoor light energy harvesting meter but would not necessarily be required. However, a mechanism to reset a system clock may be needed for operation of the indoor light energy harvesting meter.

Using measurable power loss transfer functions between the various electronic components, controller software would translate the load's power consumption back to the amount of power being harvested from the environment's illumination. This instantaneous power may also be integrated versus time to give the total energy harvested since the device was deployed and the clock started. Such measurement may be independent of the illumination source and lux levels.

In an aspect, the photovoltaic cells in the solar module may be, but need not be limited to, thin-film GaAs photovoltaic cells, including single-junction and multi junction GaAs photovoltaic cells. These types of photovoltaic cells may be flexible, lightweight, and highly efficient, which makes them suitable for demanding autonomous power applications ranging from indoor light harvesting to spacecraft.

In order to provide for a flexible, thin, lightweight, and/or low-power indoor light energy harvesting meter (also referred to as an indoor Harvestable Energy Meter or HEM) that may be used to characterize indoor light environment for different applications, including the installation and operation of IoT devices, the indoor light energy harvesting meter may be configured to have various functionalities. Such functionalities may include the ability to evaluate harvestable light energy for a given indoor location, using components with low power consumption, having a flexible-format energy storage (e.g. a battery or supercapacitor), and having a display capable of displaying one or more parameters including an accumulated time since reset (e.g., hours), accumulated harvestable power (Watt-hours per cm²), instantaneous harvestable power (Watts per cm²), and/or peak instantaneous power (Watts per cm²). Additional functionalities and/or features of the indoor light energy harvesting meter may include a button or mechanism to reset accumulator, a flexible package including small, flat electronic components, and/or a connector to allow software programming/updating

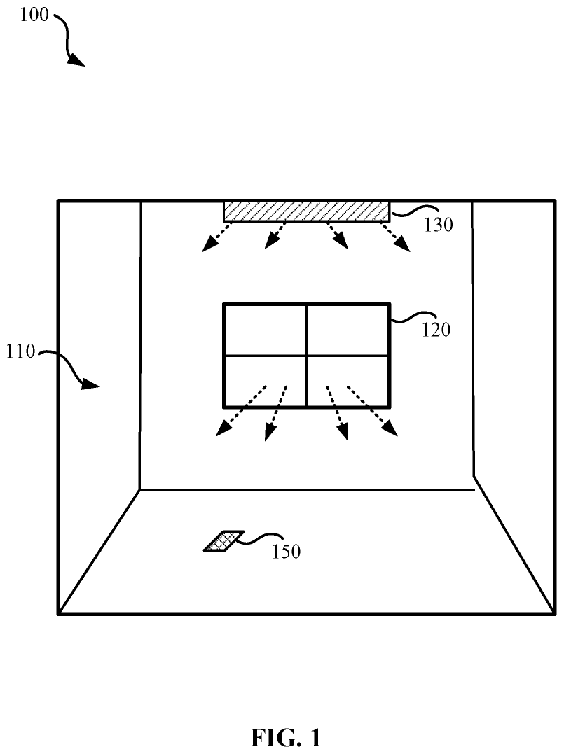

FIG. 1 shows a diagram 100 that illustrates an example of an indoor environment 110, in accordance with aspects of this disclosure. The indoor environment 110 may represent a room or other space within which light energy is available for harvesting or capturing from an artificial source 130 (e.g., lamps, ceiling lights, wall lights) and/or from outdoor light energy (e.g. solar light) that enters the indoor environment 110 through an opening 120 (e.g., a window, a glass wall). In some instances, the available light energy in a particular location and/or time may be mostly or solely from artificial sources. The amount of light energy that is available for harvesting may vary depending on, for example, the location or position within the indoor environment 110 and the time (e.g., cycle time of room lights, amount of outdoor light received indoors based on time of day).

Also shown in FIG. 1 is an indoor light energy harvesting meter 150 that may be positioned in many different places within the indoor environment 110 for monitoring and/or measuring the harvestable light energy.

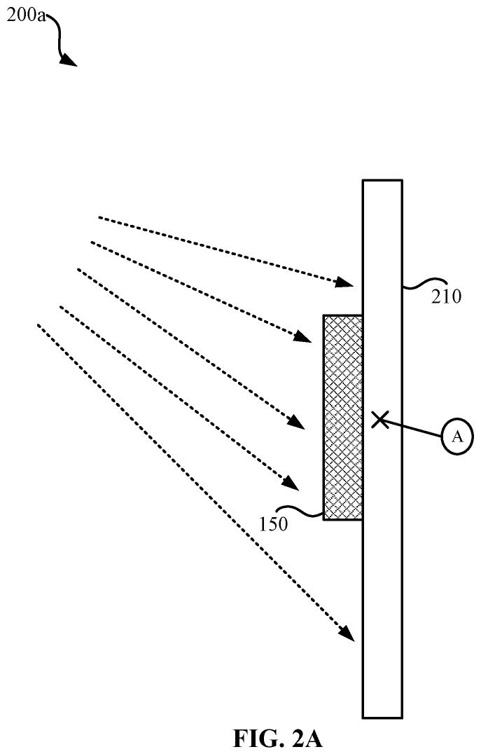

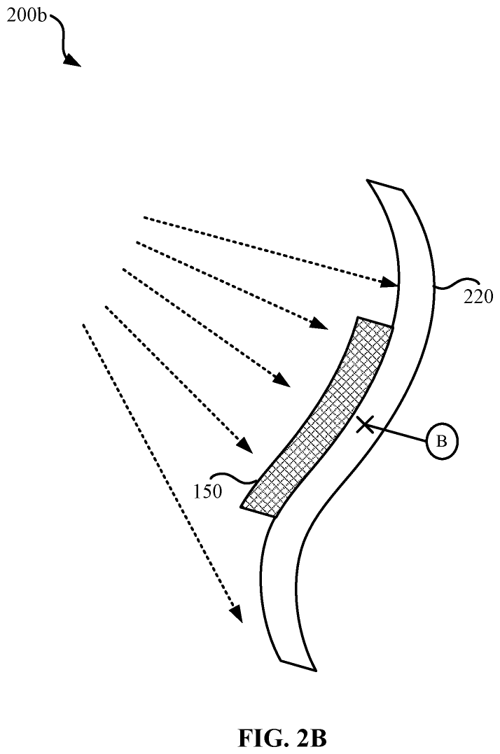

FIGS. 2A and 2B show diagrams 200a and 200b, respectively, with examples of the indoor light energy harvesting meter 150 placed on different types of surfaces, in accordance with aspects of this disclosure. The indoor light energy harvesting meter 150 may have a flexible configuration that allows for it to be placed in a position (“A”) on a flat surface 210 (as shown in the diagram 200a) but also for it to be placed in a position (“B”) on a curved or non-flat surface 220 (as shown in the diagram 200b). Having this flexible configuration allows the indoor light energy harvesting meter 150 to be used to characterize different types of positions within the indoor environment 110 that may optimize the operation of a particular IoT device. That is, if a certain type of IoT device/data gathering device/activation device would operate optimally on a curved or non-flat surface, the indoor light energy harvesting meter 150 may adapt to such a surface to obtain an accurate characterization of the available light energy for harvesting at a position on that curved or non-flat surface.

While the indoor light energy harvesting meter 150 is shown as having a flexible configuration the disclosure need not be so limited and there may be implementation in which the indoor light energy harvesting meter 150 may have a fixed, rigid, or non-flexible configuration, or may be partially flexible where only a portion is flexible and the rest is non-flexible or rigid. In some configurations, for example, there may be a flexible portion that is used to receive the harvestable energy (e.g., a solar cell or solar module) and this flexible portion may be able to conform to a contour of the curved or non-flat surface 220, while a non-flexible, rigid, or less flexible portion of the indoor light energy harvesting meter 150, which is connected to the flexible portion, does not conform, or does not conform as well, to the contour of the curved or non-flat surface 220.

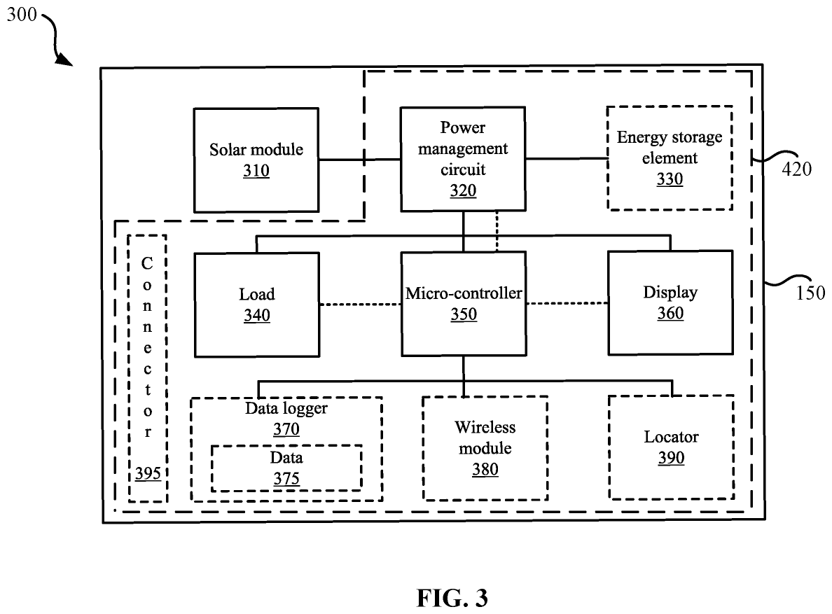

FIG. 3 shows a block diagram 300 that illustrates an example of an architecture of the indoor light energy harvesting meter 150, in accordance with aspects of this disclosure. Some of the features or components of the indoor light energy harvesting meter 150 have been described above, however, the block diagram 300 represents one possible implementation of those features or components. Optional components in this implementation may be shown by dashed lines.

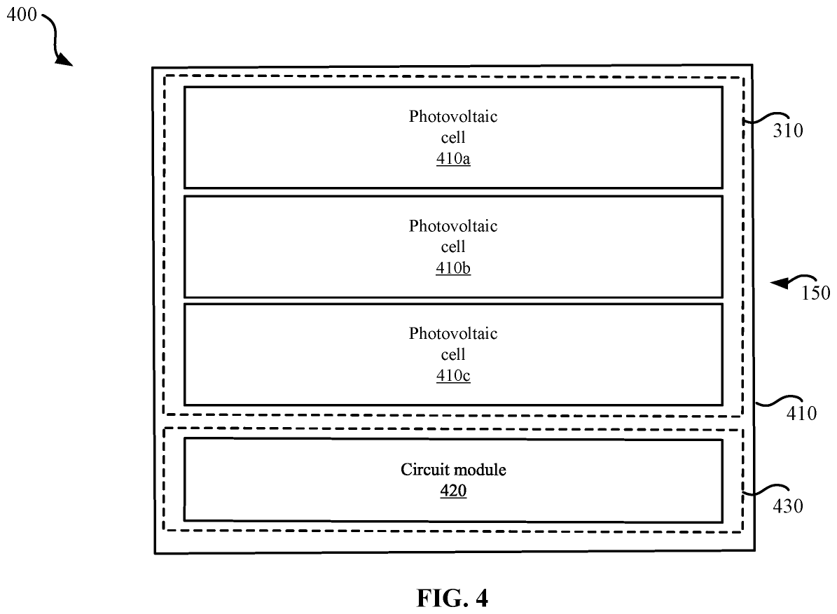

The architecture of the indoor light energy harvesting meter 150 described in the block diagram 300 includes a solar module 310 including at least one photovoltaic cell (see e.g., photovoltaic cells 410a, 410b, and 410c in FIG. 4) to capture ambient light energy, and a circuit module 420 (see e.g., circuit module 420 in FIG. 4) coupled to the solar module. The circuit module 420 may include the various electronic components of the indoor light energy harvesting meter 150 (as shown by the dashed line around various electrical and electronic components in the block diagram 300).

The circuit module 420 may include a power management circuit 320 configured to convert the ambient light energy captured by the solar module into electric energy, and a micro-controller 350 configured to control the power management circuit 320 and to receive the electric energy from the power management circuit 320 to monitor an amount of indoor harvestable power.

The indoor light energy harvesting meter 150 may further include a display 360 (e.g., within the circuit module 420) coupled to the micro-controller 350 and configured to display one or more parameters associated with the amount of indoor harvestable power. The micro-controller 350 monitors the amount of indoor harvestable power and generates one or more parameters including one or more of an accumulated harvestable power, an instantaneous harvestable power, or a peak instantaneous harvestable power.

The indoor light energy harvesting meter 150 may further include a data logger 370 (e.g., within the circuit module 420) configured to store data 375 associated with the one or more parameters generated by the micro-controller 350.

The indoor light energy harvesting meter 150 may further include a connector 395 (e.g., within the circuit module 420), where the data logger 370 can be configured to be accessible via the connector 395 to retrieve at least a portion of the data 375 associated with the one or more parameters. In an aspect, the micro-controller 350 may be programmable via the connector 395.

The indoor light energy harvesting meter 150 may further include a load 340 (e.g., within the circuit module 420). The load 340 may be used as described above to translate the load's power consumption back to an amount of power being harvested from the environment's illumination.

In an aspect, the load 340 can be a resistive load. In another aspect, the load 340 can also provide a visual indication of the operation of the indoor light energy harvesting meter 150 (e.g., LED).

The indoor light energy harvesting meter 150 may further include an energy storage element 330 (e.g., within the circuit module 420) coupled to the power management circuit 320. The energy storage element 330 can include a battery or a supercapacitor to store at least a portion of the electric energy.

The indoor light energy harvesting meter 150 may further include a wireless module 380 (e.g., within the circuit module 420) coupled to the micro-controller 350 and configured to wirelessly transmit information about the amount of indoor harvestable power monitored by the micro-controller 350. In an aspect, the micro-controller 350 may be programmable via the wireless module 380. The wireless module 380 may be configured to support one or more wireless standards including Wi-Fi, Bluetooth, ZigBee, or WiMax.

The indoor light energy harvesting meter 150 may further include a locator 390 (e.g., within the circuit module 420) coupled to the micro-controller 350 and configured to identify a geographical position or location of the indoor light energy harvesting meter 150. In an aspect, the locator 390 is a global positioning system locator that supports global position system (GPS), Galileo, or GLONASS global navigation satellite systems.

FIG. 4 shows a diagram 400 that illustrates an example of a flexible packaging of the indoor light energy harvesting meter 150, in accordance with aspects of this disclosure. In the diagram 400 there is shown the solar module 310 having at least one photovoltaic cell. In this example, there are three photovoltaic cells 410a, 410b, and 410c placed on a flexible packaging or flexible substrate 410 on which the solar module 310 with the photovoltaic cells (e.g., flexible photovoltaic cells) and the circuit module 420 are disposed. In other examples, more or fewer photovoltaic cells may be used. The components of the circuit module 420 may be disposed on a flexible circuit 430, which in turn may be disposed on the flexible packaging 410.

Each of the photovoltaic cells 410a, 410b, and 410c is a GaAs cell configured to capture ambient light energy under low lighting conditions. Other types of photovoltaic cells may also be used (e.g., multi junction Si-based cells) that have sufficient efficiency to operate a low light conditions such as those found in indoor environments. In an aspect, the GaAs cell is a thin-film flexible cell (e.g., single-junction or multi junction GaAs cell) such as those produced by epitaxial growth from a growth substrate and removed through some form of liftoff process such as an epitaxial liftoff (ELO) process or laser liftoff (LLO) process, for example.

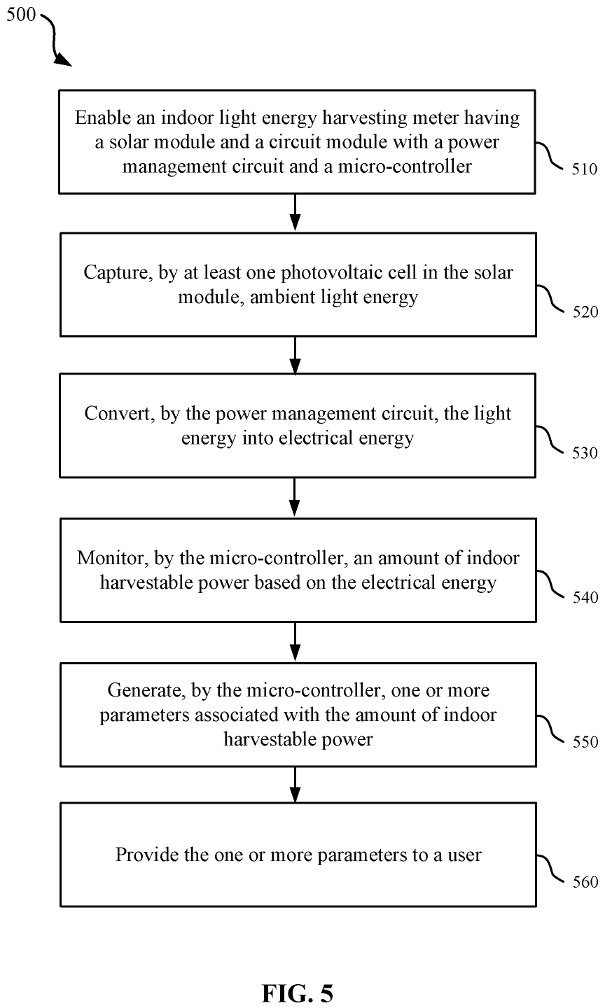

FIG. 5 illustrates an example of a flow diagram of a process or method 500 for operating an indoor light energy harvesting meter such as the indoor light energy harvesting meter 150 to determine indoor light energy harvesting conditions, in accordance with aspects of this disclosure.

The method 500, at 510, includes enabling an indoor light energy harvesting meter (e.g., the indoor light energy harvesting meter 150) having a solar module (e.g., the solar module 310) and a circuit module (e.g., the circuit module 420) with a power management circuit (e.g., the power management circuit 320) and a micro-controller (e.g., the micro-controller 350).

The method 500, at 520, includes capturing, by at least one photovoltaic cell (e.g., one or more of the photovoltaic cells 410a, 410b, and 410c) in the solar module, ambient light energy.

The method 500, at 530, includes converting, by the power management circuit, the light energy into electrical energy.

The method 500, at 540, includes monitoring, by the micro-controller, an amount of indoor harvestable power based on the electrical energy.

The method 500, at 550, includes generating, by the micro-controller, one or more parameters associated with the amount of indoor harvestable power.

The method 500, at 560, includes providing the one or more parameters to a user. The parameters provided to the user may then be used to determine an optimal operating condition and/or placement for a self-powered IoT device.

In an aspect of the method 500, providing the one or more parameters including displaying (e.g., by the display 360) the one or more parameters or making accessible (e.g., via the connector 495 and/or the wireless module 380) data associated with the one or more parameters stored in a data logger (e.g., the data 375 in the data logger 370) in the light energy harvesting meter.

In another aspect of the method 500, wherein the one or more parameters include one or more of an accumulated harvestable power, an instantaneous harvestable power, or a peak instantaneous harvestable power.

The above description of various embodiments of the claimed subject matter has been provided for the purposes of illustration and description. It is not intended to be exhaustive or to limit the claimed subject matter to the precise forms disclosed. Many modifications and variations will be apparent to one skilled in the art. Implementations were chosen and described in order to best describe certain principles and practical applications, thereby enabling others skilled in the relevant art to understand the subject matter, the various implementations, and the various modifications that are suited to the particular uses contemplated. It is therefore intended that the scope of the techniques described herein be limited not by this Detailed Description, but rather by any claims that issue on an application based hereon. Accordingly, the disclosure of various implementations is intended to be illustrative, but not limiting, of the scope of the embodiments, which is set forth in the following claims.

1. An indoor light energy harvesting meter, comprising:
a solar module including at least one photovoltaic cell to capture ambient light energy; and
a circuit module coupled to the solar module and including:
a power management circuit configured to convert the ambient light energy captured by the solar module into electric energy; and
a micro-controller configured to control the power management circuit and to receive the electric energy from the power management circuit to monitor an amount of indoor harvestable power.

2. The indoor light energy harvesting meter of claim 1, further comprising a display coupled to the micro-controller and configured to display one or more parameters associated with the amount of indoor harvestable power.

3. The indoor light energy harvesting meter of claim 1, wherein the micro-controller monitors the amount of indoor harvestable power and generates one or more parameters including one or more of an accumulated harvestable power, an instantaneous harvestable power, or a peak instantaneous harvestable power.

4. The indoor light energy harvesting meter of claim 3, further comprising a data logger configured to store data associated with the one or more parameters generated by the micro-controller.

5. The indoor light energy harvesting meter of claim 4, further comprising a connector, wherein the data logger is configured to be accessible via the connector to retrieve at least a portion of the data associated with the one or more parameters.

6. The indoor light energy harvesting meter of claim 1, further including a load from which to determine the amount of indoor harvestable power.

7. The indoor light energy harvesting meter of claim 1, further including an energy storage element coupled to the power management circuit.

8. The indoor light energy harvesting meter of claim 7, wherein the energy storage element includes a battery or a supercapacitor to store at least a portion of the electric energy.

9. The indoor light energy harvesting meter of claim 1, further comprising a connector, wherein the micro-controller is programmable via the connector.

10. The indoor light energy harvesting meter of claim 1, further comprising a flexible packaging on which the solar module and the circuit module are disposed.

11. The indoor light energy harvesting meter of claim 10, further comprising a flexible circuit with the power management circuit and the micro-controller, wherein the flexible circuit is disposed on the flexible packaging.

12. The indoor light energy harvesting meter of claim 1, wherein the at least one photovoltaic cell is a GaAs cell configured to capture ambient light energy under low lighting conditions.

13. The indoor light energy harvesting meter of claim 12, wherein the GaAs cell is a flexible cell.

14. The indoor light energy harvesting meter of claim 1, further comprising a wireless module coupled to the micro-controller and configured to wirelessly transmit information about the amount of indoor harvestable power monitored by the micro-controller.

15. The indoor light energy harvesting meter of claim 14, wherein the micro-controller is programmable via the wireless module.

16. The indoor light energy harvesting meter of claim 14, wherein the wireless module supports one or more wireless standards including Wi-Fi, Bluetooth, ZigBee, or WiMax.

17. The indoor light energy harvesting meter of claim 1, further comprising a locator coupled to the micro-controller and configured to identify a geographical position or location of the indoor light energy harvesting meter.

18. The indoor light energy harvesting meter of claim 17, wherein the locator is a global positioning system locator that supports global position system (GPS), Galileo, or GLONASS global navigation satellite systems.

19. A method for determining indoor light energy harvesting conditions, comprising:
enabling an indoor light energy harvesting meter having a solar module and a circuit module with a power management circuit and a micro-controller;
capturing, by at least one photovoltaic cell in the solar module, ambient light energy; converting, by the power management circuit, the light energy into electrical energy; monitoring, by the micro-controller, an amount of indoor harvestable power based on the electrical energy;
generating, by the micro-controller, one or more parameters associated with the amount of indoor harvestable power; and
providing the one or more parameters to a user.

20. The method of claim 19, wherein providing the one or more parameters including displaying the one or more parameters or making accessible data associated with the one or more parameters stored in a data logger in the light energy harvesting meter.

21. The method of claim 19, wherein the one or more parameters include one or more of an accumulated harvestable power, an instantaneous harvestable power, or a peak instantaneous harvestable power.
